(19) United States
(12) Patent Application Publication
(10) Pub. No.: US 2020/0105694 A1
(43) Pub. Date: Apr. 2, 2020

(54) OPEN PAD STRUCTURE AND SEMICONDUCTOR PACKAGE COMPRISING THE SAME

(71) Applicant: SAMSUNG ELECTRONICS CO., LTD., Suwon-si (KR)

(72) Inventors: Young Gwan Ko, Suwon-si (KR); Han Ui Lee, Suwon-si (KR)

(73) Assignee: SAMSUNG ELECTRONICS CO., LTD., Suwon-si (KR)

(21) Appl. No.: 16/418,865

(22) Filed: May 21, 2019

(30) Foreign Application Priority Data
Oct. 1, 2018 (KR) 10-2018-0116807

(51) Int. Cl. H01L 23/00; H01L 23/31; H01L 23/29; H01L 23/522; H01L 23/528; H05K 1/18; H01L 25/065

(52) U.S. Cl. CPC H01L 24/09; H01L 23/3171; H01L 23/295; H01L 23/5226; H01L 23/5283; H01L 24/17; H01L 2224/0401; H05K 1/181; H01L 25/0652; H01L 2224/02373; H01L 2224/02377; H01L 2224/02379; H01L 2224/02381; H01L 23/3128

(57) ABSTRACT

An open pad structure includes an insulating layer; a first pad disposed on the insulating layer; a second pad disposed on the insulating layer and spaced apart from the first pad; and a passivation layer disposed on the insulating layer, covering the first and second pads, and having an opening for opening at least a portion of each of the first and second pads. The passivation layer covers the insulating layer between the first and second pads in the opening, and t1 and t2 satisfy t1>t2, in which a thickness of a region of the passivation layer other than the opening, and t2 is a thickness of a region of the passivation layer between the first and second pads.

### CROSS-REFERENCE TO RELATED APPLICATION(S)

This application claims benefit of priority to Korean

Patent Application No. 10-2018-0116807 filed on Oct. 1, 2018 in the Korean Intellectual Property Office, the disclosure of which is incorporated herein by reference in its entirety.

### BACKGROUND

The present disclosure relates to an open pad structure for mounting an electronic component and a semiconductor package, a fan-out semiconductor package, for example, comprising the same.

As a method of forming a solder resist opening (SRO), a solder mask defined (SMD) method and a non-solder mask defined (NSMD) method have been used. Generally, an SMD refers to a structure for forming an SRO smaller than a metal pad, and an NSMD refers to a structure for forming an SRO greater than a metal pad.

### SUMMARY

An aspect of the present disclosure is to provide an open pad structure including an opening structure with high reliability, in which a thermosetting material may be used as a material of a passivation layer such that reliability may improve, a coefficient of thermal expansion (CTE) miss-match issue maybe resolved, a process maybe simplified, and the like, which may prevent a component from being lifted after being mounted and may prevent degradation of joint strength, which may improve assembly reliability such as controlling void formation between an SR and a component during an epoxy molding process, and which may prevent an over-processing defect, a miss-processing defect, and the like, during an SRO process, and a semiconductor package in which an electronic component is mounted using the open pad structure.

According to an aspect of the present disclosure, an opening for opening at least a portion of each of first and second pads may be formed on a passivation layer covering the first and second pads spaced apart from each other on an insulating layer, and a passivation layer between the first and second pads in the opening may be additionally processed, thereby providing an opening having a special form.

According to an aspect of the present disclosure, an open pad structure includes an insulating layer; a first pad disposed on the insulating layer; a second pad disposed on the insulating layer and spaced apart from the first pad; and a passivation layer disposed on the insulating layer, covering the first and second pads, and having an opening for opening at least a portion of each of the first and second pads. The passivation layer covers the insulating layer between the first and second pads in the opening, and t1 and t2 satisfy t1>t2 in which t1 is a thickness of a region of the passivation layer other than the opening, and t2 is a thickness of a region of the passivation layer between the first and second pads in the opening.

According to an aspect of the present disclosure, a semiconductor package includes a semiconductor chip having a connection pad; an encapsulant covering at least a portion of the semiconductor chip; an interconnect structure disposed on the semiconductor chip and the encapsulant and including a redistribution layer electrically connected to the connection pad; and a passivation layer disposed on the interconnect structure and covering at least a portion of the redistribution layer. The redistribution layer includes first and second pads spaced apart from each other, the passivation layer has an opening for opening at least a portion of each of the first and second pads, the passivation layer covers the interconnect structure between the first and second pads in the opening, and t1 and t2 satisfy t1>t2, in which t1 is a thickness of a region of the passivation layer other than the opening, and t2 is a thickness of a region of the passivation layer between the first and second pads in the opening.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective diagram illustrating an example of an electronic device;

FIGS. 3A and 3B are schematic cross-sectional diagrams illustrating states of a fan-in semiconductor package before and after a packaging process;

FIG. 4 is a schematic cross-sectional diagram illustrating a process of packaging a fan-in semiconductor package;

FIG. 5 is a schematic cross-sectional diagram illustrating an example in which a fan-in semiconductor package is mounted on a printed circuit board and mounted on a mainboard of an electronic device;

FIG. 6 is a schematic cross-sectional diagram illustrating an example in which a fan-in semiconductor package is mounted in a printed circuit board and mounted on a mainboard of an electronic device;

FIG. 7 is a schematic cross-sectional diagram illustrating a fan-out semiconductor package;

FIG. 8 is a schematic cross-sectional diagram illustrating an example in which a fan-out semiconductor package is mounted on a mainboard of an electronic device;

FIG. 9 is a schematic plan diagram illustrating an example of a substrate structure;

FIG. 10 is a schematic cross-sectional diagram illustrating a substrate structure illustrated in FIG. 9 taken along lines I-I′;

FIG. 11 is a schematic cross-sectional diagram illustrating an example in which an electronic component is mounted on a substrate structure;

FIG. 12 is a schematic process diagram illustrating a process of manufacturing a substrate structure;

FIG. 13 is a schematic plan diagram illustrating another example of a substrate structure;

FIG. 14 is a schematic cross-sectional diagram illustrating a substrate structure illustrated in FIG. 13 taken along lines II-II′;

FIG. 15 is a schematic cross-sectional diagram illustrating an example in which an electronic component is mounted on a substrate structure;

FIG. 16 is a schematic plan diagram illustrating another example of a substrate structure;

FIG. 17 is a schematic cross-sectional diagram illustrating a substrate structure illustrated in FIG. 16 taken along lines III-III′;

FIG. 18 is a schematic cross-sectional diagram illustrating an example in which an electronic device is mounted on a substrate structure;

FIG. 19 is a schematic diagram illustrating an example of a fan-out semiconductor package; and

FIG. 20 is a schematic diagram illustrating another example of a fan-out semiconductor package.

### DETAILED DESCRIPTION

Hereinafter, example embodiments of the present disclosure will be described with reference to the accompanying drawings. In the drawings, shapes, sizes, and the like, of elements may be exaggerated or briefly illustrated for clarity of description.

### Electronic Device

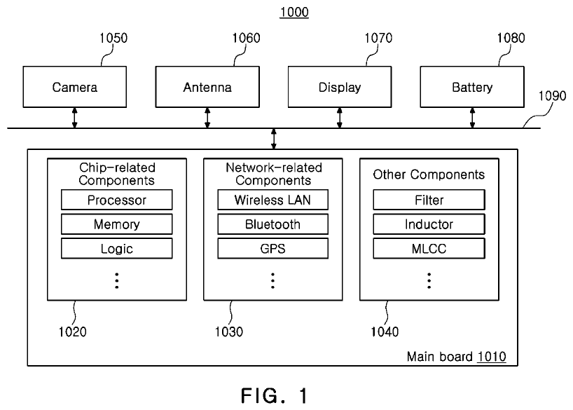

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 maybe combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

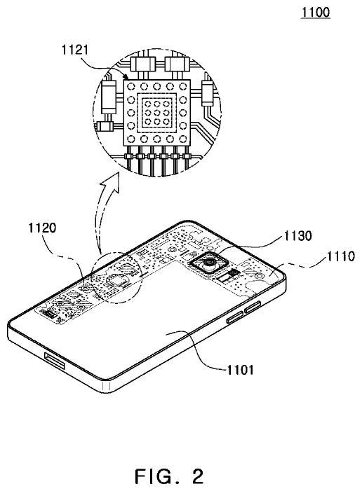

FIG. 2 is a schematic perspective diagram illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 maybe the chip related components, for example, a semiconductor package 1121, but are not limited thereto. The electronic device is not necessarily limited to the smartphone 1100, but may be other electronic devices as described above.

### Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will be described in greater detail with reference to the drawings.

### Fan-In Semiconductor Package

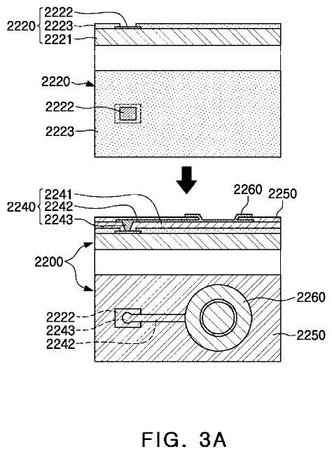

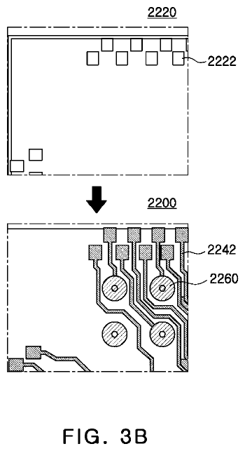

FIGS. 3A and 3B are schematic cross-sectional diagrams illustrating states of a fan-in semiconductor package before and after a packaging process.

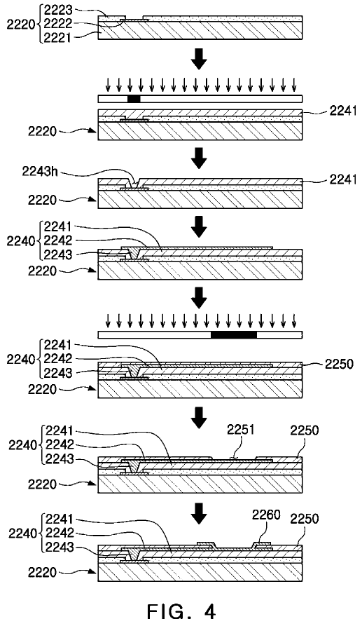

FIG. 4 is a schematic cross-sectional diagram illustrating a process of packaging a fan-in semiconductor package.

Referring to the diagrams, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 maybe formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, maybe formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even though a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip are not enough to directly mount the fan-in semiconductor package on the mainboard of the electronic device.

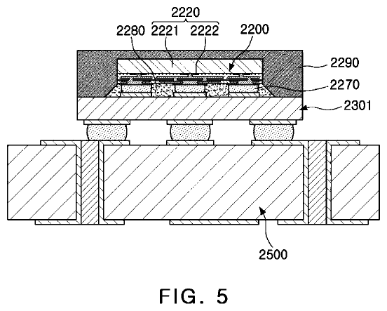

FIG. 5 is a schematic cross-sectional diagram illustrating an example in which a fan-in semiconductor package is mounted on a printed circuit board and mounted on a mainboard of an electronic device.

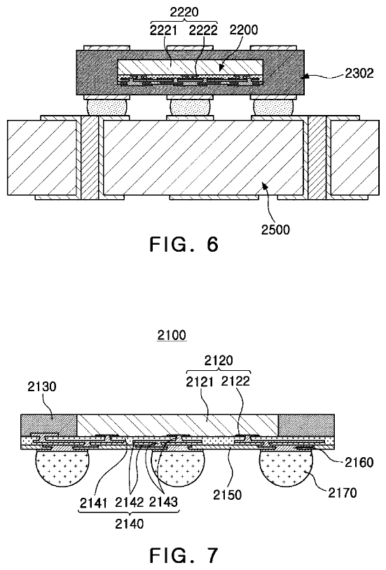

FIG. 6 is a schematic cross-sectional diagram illustrating an example in which a fan-in semiconductor package is mounted in a printed circuit board and mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

### Fan-Out Semiconductor Package

FIG. 7 is a schematic cross-sectional diagram illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

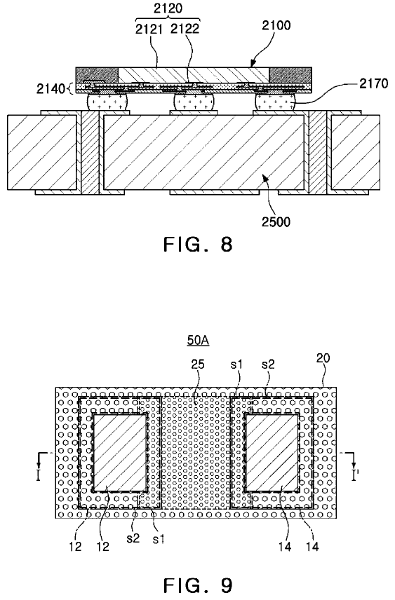

FIG. 8 is a schematic cross-sectional diagram illustrating an example in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package maybe implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

In the description below, an open pad structure including an opening structure with high reliability, in which a thermosetting material may be used as a material of a passivation layer such that reliability may improve, a CTE miss-match issue may be resolved, a process may be simplified, and the like, which may prevent a component from being lifted after being mounted and may prevent degradation of joint strength, which may improve assembly reliability such as controlling void formation between an SR and a component during an epoxy molding process, and which may prevent an over-processing defect, a miss-processing defect, and the like, during an SRO process. A semiconductor package in which an electronic component is mounted through the open pad structure will be described.

FIG. 9 is a schematic plan diagram illustrating an example of a substrate structure.

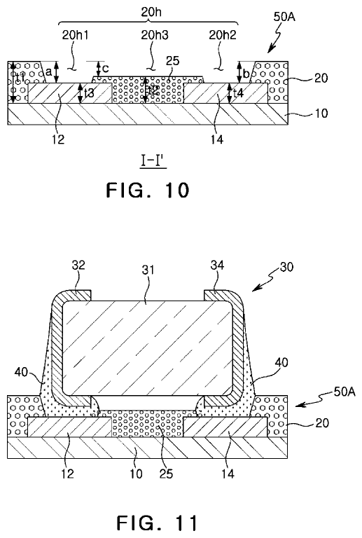

FIG. 10 is a schematic cross-sectional diagram illustrating a substrate structure illustrated in FIG. 9 taken along lines I-I′.

Referring to the diagrams, a substrate structure 50A in the example embodiment may include an insulating layer 10, a first pad 12 disposed on the insulating layer 10, a second pad 14 disposed on the insulating layer 10 and spaced apart from the first pad 12, a passivation layer 20 disposed on the insulating layer 10, covering the first and second pads 12 and 14, and having an opening 20h exposing at least a portion of each of the first and second pads 12 and 14. The passivation layer 20 may have a region 25 covering the insulating layer 10 between the first and second pads 12 and 14 in the opening 20h. The opening 20h may include first and second openings 20h1 and 20h2 exposing at least a portion of a surface of each of the first and second pads 12 and 14, and a third opening 20h3 penetrating a portion of the passivation layer 25 between the first and second pads 12 and 14 and exposing a surface of the passivation layer 25 between the first and second pads 12 and 14. The first to third openings 20h1, 20h2, and 20h3 may be connected and included in a single opening 20h. When a thickness of a region formed on the insulating layer 10 other than the opening 20h of the passivation layer 20 is t1, a thickness of the region 25 between the first and second pads 12 and 14 in the opening 20h of the passivation layer 20 is t2, a thickness of the first pad 12 is t3, and a thickness of the second pad 14 is t4, t1, t2, t3, and t4 satisfy t1>t2, and may satisfy t2≥t3 and t2≥t4 preferably. Such a region of the passivation layer 20 having the thickness t1 may not overlap with the first pad 12 or the second pad 14 in a stacking direction of the passivation layer 20 and the insulating layer 10, and may be formed directly on the insulating layer 10. More preferably, when a depth of the first opening 20h1 to an exposed surface of the first pad 12 is a, a depth of the second opening 20h2 to an exposed surface of the second pad 14 is b, and a depth of the third opening 20h3 to an exposed surface of the passivation layer 25 between the first and second pads 12 and 14 is c, a, b, and c satisfy a≥c and b≥c. The sign “=” indicates that the elements are substantially the same.

Generally, in a package substrate, an SR is formed using a photocurable material, and an SRO is formed using an exposure and developing process. However, a photocurable material may have relatively low reliability as compared to a thermosetting material, and a base substrate may be opened during an NSMD process such that the base substrate may be opened externally before an epoxy molding process or an underfill process, and may thus be vulnerable to foreign objects. Recently, there has been an attempt to use a thermosetting material as a material of an SR to improve reliability, to resolve CTE miss-match issue, to simplify a process, and the like. However, although reliability of a thermosetting material may be excellent, but a technique to control a depth of a laser or a plasma may be required, and when a process ability is insufficient or abnormalities occur during a process, miss-process defects or over-process defects may occur. For example, in a case in which a thermosetting material is used, when an SRO process is performed, as a metal pad to form a barrier in an SMD structure, there may be no significant difficulty in process, but in an NSMD structure, conditions for a laser process or a plasma process may need to be optimized such that a process height may need to be adjusted to a middle point between a metal pad and an SR. However, due to limitations in process ability, it may not be easy to adjust a process depth, and accordingly, an over-process or a miss-process may be occurred.

In the substrate structure 50A in the example embodiment, the opening 20h may include the first to third openings 20h1, 20h2, and 20h3. For example, the first and second openings 20h1 and 20h2 may be processed using an SMD method to open at least portions of the first and second pads 12 and 14 such that the passivation layer 20 covers an edge of a surface of each of the first and second pads 12 and 14, and a residue defect of the passivation layer 20 and a delamination defect of the first and second pads 12 and 14 may be prevented. The third opening 20h3 may be formed by additionally processing a region between the first and second pads 12 and 14. Accordingly, even when the passivation layer 20 includes a thermosetting material, a process depth of the third opening 20h3, c, may easily be controlled in accordance with thicknesses of the first and second pads 12 and 14 using a laser process or a plasma process, and the issue of an over-process or a miss-process may thus be prevented. Also, by processing the third opening 20h3, a component maybe prevented from being lifted after being mounted, degradation of joint strength may be prevented, and assembly reliability such as controlling a void between the passivation layer 25 between the first and second pads 12 and 14 and a component during a molding process may improve.

When the thicknesses t3 and t4 of the first and second pads 12 and 14 are less than a thickness of a general pad, and the thickness t1 of the passivation layer 20 is greater than a thickness of a general passivation layer, the process depth c of the third opening 20h3 may be controlled such that the thickness t2 of the passivation layer 25 between the first and second pads 12 and 14 may be greater than the thicknesses t3 and t4 of the first and second pads 12 and 14. When the thicknesses t3 and t4 of the first and second pads 12 and 14 are greater than a thickness of a general pad, and the thickness t1 of the passivation layer 20 is less than a thickness of a general passivation layer, the process depth c of the third opening 20h3 may be controlled such that the thickness t2 of the passivation layer 25 between the first and second pads 12 and 14 may be the same as the thicknesses t3 and t4 of the first and second pads 12 and 14. In this case, the issues of an over-process or a miss-process, the lifting of a component after being mounted, and degradation of joint strength may be prevented, and assembly reliability such as controlling void formation between the passivation layer 25 between the first and second pads 12 and 14 and a component during an epoxy molding process may easily improve.

Regions covering edges of surfaces of the first and second pads 12 and 14 of the passivation layer 20 may have a first region s1 having a thickness substantially the same as a thickness of the region 25 between the first and second pads 12 and 14, and a second region S2 having a thickness greater than a thickness of the region 25 between the first and second pads 12 and 14, a thickness substantially the same as a region other than the opening 20h, for example. When an area of the second region S2 is greater than an area of the first region s1, a delamination defect of the first and second pads 12 and 14 may easily be prevented.

In the description below, elements included in the substrate structure 50A will be described in greater detail.

The insulating layer 10 may include an insulating material. The insulating material may be a thermosetting resin such as an epoxy resin, a thermoplastic resin such as a polyimide resin, a resin in which the thermosetting resin or the thermoplastic resin is mixed with an inorganic filler, such as ajinomoto build-up film (ABF), or a resin in which the above-described resin is impregnated together with an inorganic filler in a core material as a glass fiber (or a glass cloth or a glass fabric), such as prepreg, for example. If desired, a photoimageable encapsulant (PIE) resin may also be used. An insulating material of the insulating layer 10 may not be limited to any particular material.

The first and second pads 12 and 14 may allow an electronic component to be mounted on the insulating layer 10. As a material of the first and second pads 12 and 14, a metal material such as copper (Cu), aluminum (Al), silver (Ag), tin (Sn), gold (Au), nickel (Ni), lead (Pb), titanium (Ti), or alloys thereof may be used. The first and second pads 12 and 14 may perform various functions in accordance with a design. For example, the first and second pads 12 and 14 may be a ground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal.

The passivation layer 20 may protect the insulating layer 10 and/or the first and second pads 12 and 14. The passivation layer 20 may also include an insulating material, a thermosetting material, preferably. For example, the passivation layer 20 may be a resin in which the thermosetting resin or the thermoplastic resin is mixed with an inorganic filler, such as an ABF, for example, but a material of the passivation layer 20 is not limited thereto. The passivation layer 20 may cover at least a portion of a surface of each of the first and second pads 12 and 14, and may have an opening 20h for opening at least a portion of a surface of each of the first and second pads 12 and 14. The opening 20h may be formed by an SMD method. The opening 20h may include the first and second openings 20h1 and 20h2 opening at least a portion of a surface of each of the first and second pads 12 and 14, and a third opening 20h3 penetrating a portion of the passivation layer 25 between the first and second pads 12 and 14 and exposing a surface of the passivation layer 25 between the first and second pads 12 and 14, and the first to third openings 20h1, 20h2, and 20h3 may be connected and included in a single opening 20h. The passivation layer 20 may cover the insulating layer 10 between first and second pads 12 and 14 in the third opening 20h3 to not be exposed, and the region 25 covering the insulating layer 10 between the first and second pads 12 and 14 in the third opening 20h3 of the passivation layer 20 is more highlighted in the diagram for ease of description. As the passivation layer 20 covers overall edges of the first and second pads 12 and 14, and the region 25 covering the insulating layer 10 between the first and second pads 12 and 14 covers the insulating layer 10 to not be opened, contamination caused by an opened insulating layer 10, and the like, may easily be prevented.

When a thickness of a region other than the opening 20h of the passivation layer 20 is t1, a thickness of the region 25 between the first and second pads 12 and 14 in the opening 20h of the passivation layer 20 is t2, a thickness of the first pad 12 is t3, and a thickness of the second pad 14 is t4, t1, t2, t3, and t4 satisfy t1>t2, and may satisfy t2≥t3 and t2≥t4 preferably. More preferably, when a depth of the first opening 20h1 to an exposed surface of the first pad 12 is a, a depth of the second opening 20h2 to an exposed surface of the second pad 14 is b, and a depth of the third opening 20h3 to an exposed surface of the passivation layer 25 between the first and second pads 12 and 14 is c, a, b, and c satisfy a≥c and b≥c. The sign “=” indicates that the elements are substantially the same.

The region covering edges of surfaces of the first and second pads 12 and 14 of the passivation layer 20 may have a first region s1 having a thickness substantially the same as a thickness of the region 25 between the first and second pads 12 and 14, and a second region S2 having a thickness greater than a thickness of the region 25 between the first and second pads 12 and 14, a thickness substantially the same as a region other than the opening 20h, for example. When an area of the second region S2 is greater than an area of the first region s1, a delamination defect of the first and second pads 12 and 14 may easily be prevented.

FIG. 11 is a schematic cross-sectional diagram illustrating an example in which an electronic component is mounted on a substrate structure.

Referring to the diagram, an electronic component 30 having first and second external electrodes 32 and 34 connected to first and second pads 12 and 14, respectively, maybe disposed on a passivation layer 20, and the first and second external electrodes 32 and 34 may be connected to the first and second pads 12 and 14, respectively, using a metal having a low melting point such as tin (Sn) or an alloy including tin (Sn), a well-known bonding material such as a solder 40, for example.

The electronic component 30 may include a body 31, and the first and second external electrodes 32 and 34 disposed on both sides of the body 31, respectively. The electronic component 30 may be a passive component such as a capacitor or an inductor, and in this case, an internal electrode (not illustrated) may be disposed in the body 31 and may be electrically connected to the first and second external electrodes 32 and 34. The first and second external electrodes 32 and 34 may include a metal material such as copper (Cu), aluminum (Al), silver (Ag), tin (Sn), gold (Au), nickel (Ni), lead (Pb), titanium (Ti), or alloys thereof. The electronic component 30 maybe an integrated circuit die, and in this case, the first and second external electrodes 32 and 34 may be disposed on a lower surface of the body 31 and may be spaced apart from each other differently from the example illustrated in the diagram, and may work as a connection pad of a die. Because forming the third opening 20h3 (shown in FIG. 10) removes a portion of the passivation layer 20 in the region 25 between the first and second pads 12 and 14, the body 31 of the electronic component 30 may be spaced apart from the region 25 of the passivation layer 20 between the first and second pads 12 and 14. The descriptions of the other elements are the same as the descriptions described with reference to FIGS. 9 and 10, and thus, the detailed descriptions thereof will not be repeated.

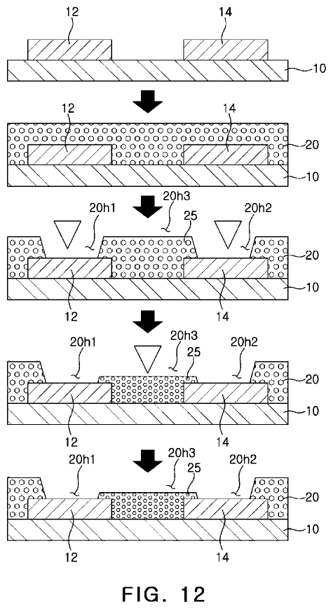

FIG. 12 is a schematic process diagram illustrating a process of manufacturing a substrate structure.

Referring to the diagram, first and second pads 12 and 14 may be formed on an insulating layer 10. The first and second pads 12 and 14 may be formed by a well-known plating method, such as an additive process (AP), a semi-AP (SAP), a modified SAP (MSAP), a tenting process, and the like, for example. A passivation layer 20 covering the first and second pads 12 and 14 may be formed on the insulating layer 10. The passivation layer 20 may be formed by laminating a thermosetting film on the insulating layer 10 and curing the thermosetting film, or by coating the insulating layer 10 with a liquid thermosetting material and curing the thermosetting film. First and second openings 20h1 and 20h2 for exposing at least a portion of a surface of each of the first and second pads 12 and 14 may be formed on the passivation layer 20 using a laser or a plasma.

The first and second openings 20h1 and 20h2 each may have an SMD structure. A third opening 20h3 for opening a surface of the passivation layer 25 may be formed by additionally processing the passivation layer 25 between the first and second pads 12 and 14 using a laser or a plasma. When an organic material carbonized by a desmear process is removed, the substrate structure 50A may be manufactured. The descriptions of the other elements are the same as the descriptions described with reference to FIGS. 9 to 11, and thus, the detailed descriptions thereof will not be repeated.

FIG. 13 is a schematic plan diagram illustrating another example of a substrate structure.

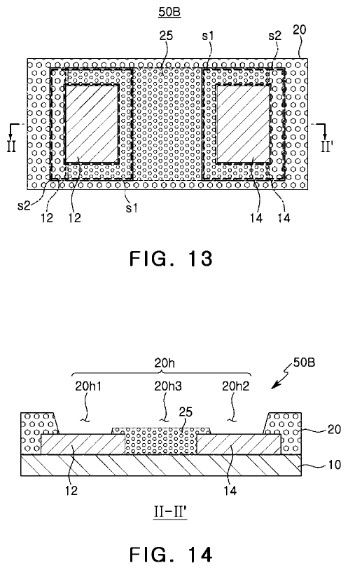

FIG. 14 is a schematic cross-sectional diagram illustrating a substrate structure illustrated in FIG. 13 taken along lines II-II′.

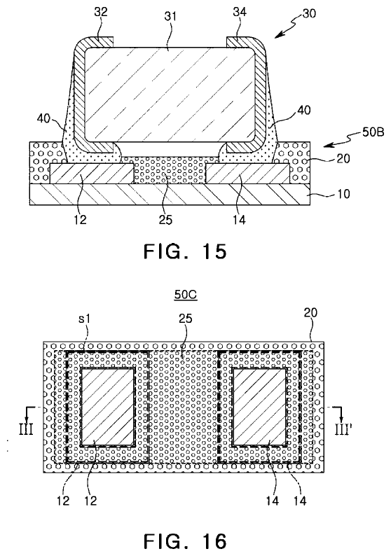

FIG. 15 is a schematic cross-sectional diagram illustrating an example in which an electronic component is mounted on a substrate structure.

Referring to the diagrams, in a substrate structure 50B in the example embodiment, a third opening 20h3 may be formed by processing a passivation layer 25 between first and second pads 12 and 14 such that an area of a first region s1 may be greater than an area of a second region S2. In a case in which an area of the second region S2 increases, a solder 40 may further spread when an electronic component 30 is mounted, and accordingly, joint reliability may improve. The descriptions of the other elements including thickness relations thereof are the same as the descriptions described with reference to FIGS. 9 to 12, and thus, the detailed descriptions thereof will not be repeated.

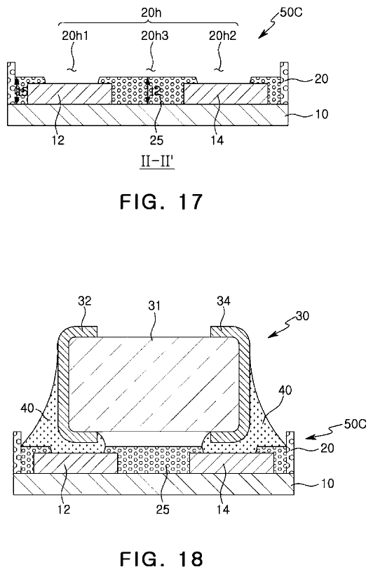

FIG. 16 is a schematic plan diagram illustrating another example of a substrate structure.

FIG. 17 is a schematic cross-sectional diagram illustrating a substrate structure illustrated in FIG. 16 taken along lines III-III′.

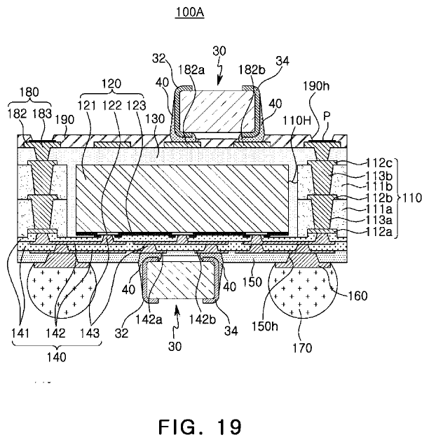

FIG. 18 is a schematic cross-sectional diagram illustrating an example in which an electronic device is mounted on a substrate structure.

Referring to the diagram, in a substrate structure 50C in the example embodiment, a third opening 20h3 may be formed by processing a passivation layer 25 between first and second pads 12 and 14 such that only a first region s1 may be formed, and a second region S2 may not be formed. Accordingly, overall thickness t5 of a region 25 covering edges of surfaces of the first and second pads 12 and 14 of the passivation layer 20 may be substantially the same as thickness t2 of the region 25 between the first and second pads 12 and 14. An opening 20h may have a plurality of stepped portions, a staircase structure, formed across opened surfaces of the first and second pads 12 and 14, an opened surface covering edges of surfaces of the first and second pads 12 and 14, and a surface of the passivation layer 20 other than the opening 20h. In this case, a solder 40 may further spread when an electronic component 30 is mounted, and thus, joint reliability may further improve. The descriptions of the other elements including thickness relations thereof are the same as the descriptions described with reference to FIGS. 9 to 15, and thus, the detailed descriptions thereof will not be repeated.

FIG. 19 is a schematic diagram illustrating an example of a fan-out semiconductor package.

Referring to the diagram, a fan-out semiconductor package 100A in the example embodiment may include a semiconductor chip 120 having a connection pad 122, an encapsulant 130 covering at least a portion of the semiconductor chip 120, a first interconnect structure 140 disposed in lower portions of the semiconductor chip 120 and the encapsulant 130 and including a first redistribution layer 142 electrically connected to the connection pad 122, a second interconnect structure 180 disposed in upper portions of the semiconductor chip 120 and the encapsulant 130 and including a second redistribution layer 182 electrically connected to the connection pad 122, a first passivation layer 150 disposed on the first interconnect structure 140 and covering at least a portion of the first redistribution layer 142, and a second passivation layer 190 disposed on the second interconnect structure 180 and covering at least a portion of the second redistribution layer 182. Additionally, if desired, the fan-out semiconductor package 100A may further include a frame 110, an under bump metal 160, an electrical connector metal 170, and the like.

The first redistribution layer 142 may include first and second pads 142a and 142b spaced apart from each other. The first passivation layer 150 may have a first opening 150h for exposing at least a portion of each of the first and second pads 142a and 142b, and may cover the first interconnect structure 140 between the first and second pads 142a and 142b in the first opening 150h. A thickness of a region other than the first opening 150h of the first passivation layer 150 may be greater than a thickness of a region between the first and second pads 142a and 142b in the first opening 150h of the first passivation layer 150. An electronic component 30 having first and second external electrodes 32 and 34 connected to the first and second pads 142a and 142b, respectively, using a solder 40, or the like, may be disposed on the first passivation layer 150. An insulating layer 141 of the first interconnect structure 140 may be used as the insulating layer 10 described in the aforementioned example embodiment, the first and second pads 142a and 142b of the first interconnect structure 140 may be used as the first and second pads 12 and 14 described in the aforementioned example embodiment, the first passivation layer 150 may be used as the passivation layer 20 described in the aforementioned example embodiment, and the first opening 150h may be used as the opening 20h described in the aforementioned example embodiment. The descriptions of the other elements may be the same as the descriptions of the substrate structure 50A illustrated in the examples in FIGS. 9 to 13, and the substrate structures 50B and 50C illustrated in the examples in FIGS. 14 to 18 may also be applied alternatively.

The second redistribution layer 182 may include third and fourth pads 182a and 182b spaced apart from each other. The second passivation layer 190 may have a second opening 190h for exposing at least a portion of each of the third and fourth pads 182a and 182b, and may cover the encapsulant 130 between the third and fourth pads 182a and 182b. A thickness of a region other than the second opening 190h of the second passivation layer 190 may be greater than a thickness of a region between the third and fourth pads 182a and 182b in the second opening 190h of the second passivation layer 190. The electronic component 30 having the first and second external electrodes 32 and 34 connected to the third and fourth pads 182a and 182b, respectively, using the solder 40, or the like, maybe disposed on the second passivation layer 190. The encapsulant 130 may be used as the insulating layer 10 described in the aforementioned example embodiment, the third and fourth pads 182a and 182b of the second interconnect structure 180 may be used as the first and second pads 12 and 14 described in the aforementioned example embodiment, the second passivation layer 190 may be used as the passivation layer 20 described in the aforementioned example embodiment, and the second opening 190h may be used as the opening 20h described in the aforementioned example embodiment. If desired, a molding material (not illustrated) covering the electronic component 30 may further be formed on the second passivation layer 190, and the molding material (not illustrated) may fill at least a portion of a space between the electronic component 30 and the second passivation layer 190 disposed between the third and fourth pads 182a and 182b. The descriptions of the other elements may be the same as the descriptions of the substrate structure 50A illustrated in the examples in FIGS. 9 to 13, and the substrate structures 50B and 50C illustrated in the examples in FIGS. 14 to 18 may also be applied alternatively.

In the description below, the elements included in the fan-out semiconductor package 100A will be described in greater detail in accordance with an example.

A frame 110 may be an additional element. The frame 110 may improve stiffness of the package 100A depending on a specific material of insulating layers 111a and 111b, and may secure uniformity of a thickness of the encapsulant 130. The frame 110 may have a through-hole 110H penetrating the insulating layers 111a and 111b. The semiconductor chip 120 may be disposed in the through-hole 110H, and a passive component (not illustrated) may be disposed together if desired. A wall of the through-hole 110H may be configured to surround the semiconductor chip 120, but an example embodiment thereof is not limited thereto. The frame 110 may further include wiring layers 112a, 112b, and 112c and wiring vias 113a and 113b in addition to the insulating layers 111a and 111b, and may thus work as an interconnect structure. The wiring layers 112a, 112b, and 112c and the wiring vias 113a and 113b may work as electrical interconnect structures. If desired, an interconnect structure having an electrical interconnect member which may provide a different form of an upper/lower electrical connection path, instead of the frame 110.

The frame 110 may include the first insulating layer 111a in contact with the interconnect structure 140, the first wiring layer 112a in contact with the first interconnect structure 140 and buried in the first insulating layer 111a, the second wiring layer 112b disposed on a portion of the first insulating layer 111a opposing a portion in which the first wiring layer 112a is buried, the second insulating layer 111b disposed on a portion of the first insulating layer 111a opposing a portion in which the first wiring layer 112a is buried and covering at least a portion of the second wiring layer 112b, and the third wiring layer 112c disposed on a portion of the second insulating layer 111b opposing a portion in which the second wiring layer 112b is buried. The first and second wiring layers 112a and 112b and the second and third wiring layers 112b and 112c may be electrically connected to each other, respectively, through the first and second wiring vias 113a and 113b penetrating the first and second insulating layers 111a and 111b. The first to third wiring layers 112a, 112b, and 112c maybe electrically connected to the connection pad 122 through the redistribution layer 142 of the first interconnect structure 140.

A material of the insulating layers 111a and 111b may not be limited to any particular material. For example, an insulating material may be used, and the insulating material may be a thermosetting resin such as an epoxy resin, a thermoplastic resin such as a polyimide resin, a resin in which the thermosetting resin or the thermoplastic resin is mixed with an inorganic filler, such as ajinomoto build-up film (ABF), or a resin in which the above-described resin is impregnated together with an inorganic filler in a core material as a glass fiber (or a glass cloth or a glass fabric), such as prepreg, for example. If desired, a photoimageable encapsulant (PIE) resin may also be used.

The wiring layers 112a, 112b, and 112c may provide an upper/lower electrical connection pad of a package along with the wiring vias 113a and 113b, and may redistribute the connection pad 122. As a material of the wiring layers 112a, 112b, and 112c, a conductive material such as copper (Cu), aluminum (Al), silver (Ag), tin (Sn), gold (Au), nickel (Ni), lead (Pb), titanium (Ti), or alloys thereof may be used. The wiring layers 112a, 112b, and 112c may perform various functions depending on a design of a respective layer. For example, the wiring layers 112a, 112b, and 112c may include aground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal. The wiring layers 112a, 112b, and 112c may include a via pad, a wire pad, an electrical connector metal pad, and the like. The wiring layers 112a, 112b, and 112c may be formed by a well-known plating process, and may include a seed layer and a conductor layer. Thicknesses of the wiring layers 112a, 112b, and 112c may be greater than a thickness of the redistribution layer 142.

The first wiring layer 112a maybe recessed internally into the first insulating layer 111a. When a stepped portion is formed between a lower surface of the first insulating layer 111a and a lower surface of the first wiring layer 112a as the first wiring layer 112a is recessed internally into the first insulating layer 111a, contamination of the first wiring layer 112a caused by bleeding of a material of the encapsulant 130 may be prevented.

The wiring vias 113a and 113b may electrically connect the wiring layers 112a, 112b, and 112c formed on different layers, and may accordingly form an electrical path in the frame 110. A material of the wiring vias 113a and 113b may be a conductive material such as copper (Cu), aluminum (Al), silver (Ag), tin (Sn), gold (Au), nickel (Ni), lead (Pb), titanium (Ti), or alloys thereof. The wiring vias 113a and 113b each may be a filled type via completely filled with a conductive material, or may be conformal type via in which a conductive material is formed along a side wall of a via hole. The wiring vias 113a and 113b each may have a tapered shape. The wiring vias 113a and 113b may be formed by a plating process, and may include a seed layer and a conductor layer.

A portion of a pad of the first wiring layer 112a may work as a stopper when a hole for the first wiring via 113a is formed, and thus, the first wiring via 113a may be configured to have a tapered shape in which a width of a top surface may be greater than a width of a bottom surface. In this case, the first wiring via 113a may be integrated with a pad pattern of the second wiring layer 112b. Also, as a portion of a pad of the second wiring layer 112b may work as a stopper when a hole for the second wiring via 113b is formed, the second wiring via 113b may be configured to have a tapered shape in which a width of a top surface may be greater than a width of a bottom surface. In this case, the second wiring via 113b may be integrated with a pad pattern of the third wiring layer 112c.

Although not illustrated, if desired, a metal layer (not illustrated) maybe disposed on a wall of the through-hole 110H of the frame 110 to prevent electromagnetic waves or to dissipate heat, and the metal layer (not illustrated) may surround the semiconductor chip 120.

The semiconductor chip 120 maybe an integrated circuit (IC) in which several hundreds to several millions or more of devices are integrated in a single chip. The integrated circuit maybe an application processor chip such as a central processor (for example, a central processing unit (CPU)), a graphics processor (for example, a graphics processing unit (GPU)), a digital signal processor, a cryptographic processor, a microprocessor, a microcontroller, or the like, but an example embodiment thereof is not limited thereto, and may also be a power management integrated circuit (PMIC), a memory chip such as a volatile memory (for example, a dynamic random access memory (DRAM)), a non-volatile memory (for example, a read only memory (ROM)), a flash memory, or the like, or a logic chip such as an analog-to-digital (ADC) converter, an application-specific integrated circuit (ASIC), or the like.

The semiconductor chip 120 maybe an integrated circuit in a bare state in which a bump or a wiring layer is not formed, but an example embodiment thereof is not limited thereto, and the semiconductor chip 120 may be a packaged type integrated circuit. An integrated circuit may be formed based on an active wafer. In this case, a silicon (Si), germanium (Ge), gallium arsenide (GaAs), and the like, may be used as a base material of the body 121 of the semiconductor chip 120. The body 121 may include various circuits. The connection pad 122 may electrically connect the semiconductor chip 120 with other elements, and a conductive material such as aluminum (Al), and the like, may be used as a material of the connection pad 122 without any particular limitation. A passivation film 123 opening the connection pad 122 may be formed on the body 121, and the passivation film 123 may be an oxide film or a nitride film, or may be a dual layer including an oxide layer and a nitride layer. An insulating film (not illustrated) may further be disposed in other desired positions. In the semiconductor chip 120, a surface on which the connection pad 122 is disposed may be an active surface, and an opposite surface may be an inactive surface. When the passivation film 123 is formed on the active surface of the semiconductor chip 120, the active surface of the semiconductor chip 120 may determine a positional relationship with reference to a lowermost surface of the passivation film 123.

The encapsulant 130 may encapsulate the frame 110 and the semiconductor chip 120, and may fill at least a portion of the through-hole 110H. The encapsulant 130 may include an insulating material, and the insulating material may be a material including an inorganic filler and an insulating resin, such as a thermosetting resin such as an epoxy resin, for example, a thermoplastic resin such as a polyimide resin, or a resin in which a reinforcement such as an inorganic filler is included in the above-described resins, such as an ABF, FR-4, BT, a resin, and the like. Also, a molding material such as an EMC may be used, and a photosensitive material such as a photoimageable encapsulant (PIE) resin may be used if desired. Also, a resin in which an insulating resin such as a thermosetting resin or a thermoplastic resin is impregnated in a core material such as an inorganic filler and/or a glass fiber (or a glass cloth or a glass fabric), and the like, may be used.

The first interconnect structure 140 may redistribute the connection pad 122 of the semiconductor chip 120. The several tens or several hundreds of connection pads 122 of the semiconductor chip 120 having various functions may be redistributed through the interconnect structure 140, and may be physically and/or electrically connected to an external entity through an electrical connector metal 170 in accordance with respective functions. The interconnect structure 140 may include one or more insulating layers 141, one or more redistribution layers 142, and one or more connection vias 143, and the number of these elements may be greater or less than the example illustrated in the diagram.

As a material of the insulating layer 141, an insulating material may be used. The insulating material may be a photosensitive insulating material (PID), and in this case, a fine pitch may be included through a photo via, and thus, the several tens to several millions of connection pads 122 of the semiconductor chip 120 may be efficiently redistributed.

The redistribution layer 142 may redistribute the connection pads 122 of the semiconductor chip 120 and electrically connect the connection pads 122 to the electrical connector metal 170. A material of the redistribution layer 142 maybe a conductive material such as copper (Cu), aluminum (Al), silver (Ag), tin (Sn), gold (Au), nickel (Ni), lead (Pb), titanium (Ti), or alloys thereof. The redistribution layer 142 may perform various functions depending on a design. For example, the redistribution layer 142 may include a ground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal. The redistribution layer 142 may include first and second pads 142a and 142b for mounting the electronic component 30. The detailed description thereof is the same as in the aforementioned example embodiment.

The connection via 143 may electrically connect the redistribution layers 142 formed on different layers, and may electrically connect the connection pad 122 of the semiconductor chip 120 to the redistribution layer 142. The connection via 143 may be physically in contact with the connection pad 122 in a case in which the semiconductor chip 120 is a bare die. A material of the connection via 143 may be a conductive material such as copper (Cu), aluminum (Al), silver (Ag), tin (Sn), gold (Au), nickel (Ni), lead (Pb), titanium (Ti), or alloys thereof. The connection via 143 may be filled with a conductive material, or a conductive material may be formed along a wall of a via. The connection via 143 may have a tapered shape.

The passivation layer 150 may protect the interconnect structure 140 from external physical and chemical damages, and the like. The passivation layer 150 may include a thermosetting resin. For example, the passivation layer 150 may be an ABF, but an example embodiment thereof is not limited thereto. The passivation layer 150 may include an opening 150h for opening at least portions of the first and second pads 142a and 142b. The detailed description thereof is the same as in the aforementioned example embodiment.

The under bump metal 160 may also be an additional elements. The under bump metal 160 may improve connection reliability of the electrical connector metal 170 and may thus improve board-level reliability of the fan-out semiconductor package 100A in the example embodiment. Several tens to several tens of thousands of the under bump metals 160 may be provided. The under bump metals 160 may penetrate the passivation layer 150 and may be connected to the redistribution layer 142. The under bump metals 160 may be formed by a well-known metallization method using a metal, but the method is not limited thereto.

The electrical connector metal 170 may also be an additional element, and may physically and/or electrically connect the semiconductor package 100A to an external entity. For example, the semiconductor package 100A may be mounted on a mainboard of an electronic device through the electrical connector metal 170. The electrical connector metal 170 may be formed of a metal having a low melting point, such as tin (Sn) or an alloy including tin (Sn), for example. For instance, the electrical connector metal 170 may be formed of a solder, but a material of the electrical connector metal 170 is not limited thereto. The electrical connector metal 170 may be a land, a ball, a pin, or the like. The electrical connector metal 170 maybe provided as a plurality of layers or a single layer. When the electrical connector metals 170 are provided as a plurality of layers, the electrical connector metals 170 may include a copper pillar and a solder, and when the electrical connector metal 170 is a single layer, the electrical connector metal 170 may include a tin-silver solder or copper, but an example embodiment thereof is not limited thereto. The number of the electrical connector metals 170, a gap between the electrical connector metals 170, an arrangement form of the electrical connector metals 170 are not limited to any particular example, and may vary depending on a design. For example, the number of the electrical connector metals 170 may be several tens to several thousands depending on the number of the connection pads 122, or may be higher or lower that the above example.

At least one of the electrical connector metals 170 may be disposed in a fan-out region. The fan-out region may refer to a region beyond a region in which the semiconductor chip 120 is disposed. A fan-out package may have improved reliability as compared to a fan-in package, and a plurality of I/O terminals may be implement, and a 3D connection may easily be implemented in a fan-out package. Also, a fan-out package may have a reduced thickness, and may be cost-competitive as compared to a ball grid array (BGA) package, a land grid array (LGA) package, or other types of packages.

The interconnect structure 180 may be electrically connected to the connection pad 122 of the semiconductor chip 120. The interconnect structure 180 may include the redistribution layer 182 disposed on the encapsulant 130, and a connection via 183 penetrating the encapsulant 130 and electrically connecting the redistribution layer 182 to the third wiring layer 112c of the frame 110. If desired, a plurality of the redistribution layers 182 and a plurality of the connection vias 183 may be provided as an insulating layer (not illustrated) is included.

The redistribution layer 182 may include a conductive material such as copper (Cu), aluminum (Al), silver (Ag), tin (Sn), gold (Au), nickel (Ni), lead (Pb), titanium (Ti), or alloys thereof. The redistribution layer 182 may perform various functions depending on a design. For example, the redistribution layer 182 may include a ground (GrouND: GND) pattern, a power (PoWeR: PWR) pattern, a signal (Signal: S) pattern, and the like. The signal (S) pattern may include various signals other than a ground (GND) pattern, a power (PWR) pattern, and the like, such as a data signal. The redistribution layer 182 may also include a via pad, a wire pad, an electrical interconnect structure pad, and the like. The redistribution layer 182 may include the third and fourth pads 182a and 182b for mounting the electronic component 30. The detailed description thereof is the same as in the aforementioned example embodiment.

The connection via 183 may electrically connect the redistribution layer 182 to the third wiring layer 112c. The connection via 183 may also include a conductive material such as copper (Cu), aluminum (Al), silver (Ag), tin (Sn), gold (Au), nickel (Ni), lead (Pb), titanium (Ti), or alloys thereof. The connection via 183 may be a filled type via completely filled with a conductive material, or may be conformal type via in which a conductive material is formed along a side wall of a via hole. The connection via 183 may have a tapered shape.

The passivation layer 190 may protect the interconnect structure 180 from external physical and chemical damages, and the like. The passivation layer 190 may include a thermosetting region. For example, the passivation layer 190 may be an ABF, but an example embodiment thereof is not limited thereto. The passivation layer 190 may include an opening 190h for opening at least portions of the third and fourth pads 182a and 182b. The detailed description thereof is the same as in the aforementioned example embodiment. A surface processing layer P such as nickel (Ni)/gold (Au), and the like, may be disposed on a surface of the redistribution layer 182 exposed by another opening of the passivation layer 190.

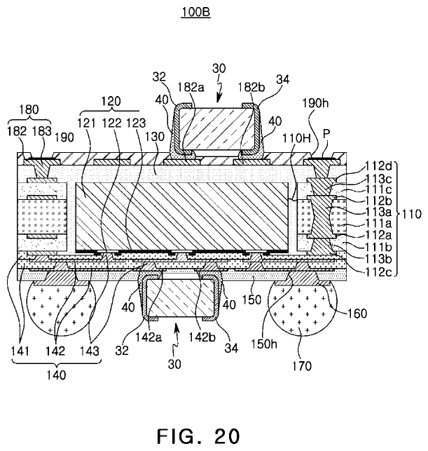

FIG. 20 is a schematic diagram illustrating another example of a fan-out semiconductor package.

Referring to the diagram, a fan-out semiconductor package 100B may have a frame 110 having a form different from the form of the frame 110 included in the fan-out semiconductor package 100A described in the aforementioned example embodiment. For example, in the fan-out semiconductor package 100B in the example embodiment, the frame 110 may include a first insulating layer 111a, a first wiring layer 112a disposed on one surface of the first insulating layer 111a, a second wiring layer 112b disposed on the other surface of the first insulating layer 111a, the second insulating layer 111b disposed on one surface of the first insulating layer 111a and covering at least a portion of the first wiring layer 112a, a third wiring layer 112c disposed on a portion of the second insulating layer 111b opposing a portion in which the first wiring layer 112a is buried, a third insulating layer 111c disposed on the other surface of the first insulating layer 111a and covering at least a portion of the second wiring layer 112b, a fourth wiring layer 112d disposed in a portion of the third insulating layer 111c opposing a portion in which the second wiring layer 112b is buried, a first wiring via 113a penetrating the first insulating layer 111a and electrically connecting the first and second wiring layers 112a and 112b, a second wiring via 113b penetrating the second insulating layer 111b and electrically connecting the first and third wiring layers 112a and 113c, and a third wiring via 113c penetrating the third insulating layer 111c and electrically connecting the second and fourth wiring layers 112b and 112d. As the frame 110 has a greater number of wiring layers 112a, 112b, 112c, and 112d, the interconnect structure 140 may further be simplified.

A thickness of the first insulating layer 111a may be greater than thicknesses of the second insulating layer 111b and the third insulating layer 111c. A thickness of the first insulating layer 111a may relatively be great to maintain stiffness, and the second insulating layer 111b and the third insulating layer 111c may be included to include a greater number of the wiring layers 112c and 112d. The first insulating layer 111a may include an insulating material different from insulating materials included in the second insulating layer 111b and the third insulating layer 111c. For example, the first insulating layer 111a may be formed of a material including a core such as glass fiber, an inorganic filler, and an insulating resin, such as prepreg, and the second insulating layer 111b and the third insulating layer 111c may be formed of an ABF or a PID including an inorganic filler and an insulating resin, but examples of the materials are not limited thereto. Similarly, the first wiring via 113a penetrating the first insulating layer 111a may have a diameter greater than diameters of the second and third wiring vias 113b and 113c penetrating the second and third insulating layers 111b and 111c. The first wiring via 113a may have an hourglass shape or a cylindrical shape, whereas the second and third wiring vias 113b and 113c may have tapered shapes, tapered in opposite directions. Thicknesses of the first to fourth wiring layers 112a, 112b, 112c, and 112d may be greater than a thickness of the redistribution layer 142. The descriptions for material, functions, and the like, of the first to fourth wiring layers 112a, 112b, 112c, and 112d and the first to third wiring vias 113a, 113b, and 113c are substantially the same as in the aforementioned example embodiments described with reference to FIGS. 9 to 19, and thus, the detailed descriptions thereof will not be repeated.

According to the aforementioned example embodiments, an open pad structure including an opening structure with high reliability, in which a thermosetting material may be used as a material of a passivation layer such that reliability may improve, a CTE miss-match issue may be resolved, a process may be simplified, and the like, which may prevent a component from being lifted after being mounted and may prevent degradation of joint strength, which may improve assembly reliability such as controlling void formation between an SR and a component during an epoxy molding process, and which may prevent an over-processing defect, a miss-processing defect, and the like, during an SRO process. A semiconductor package in which an electronic component is mounted through the open pad structure may be provided.

In the example embodiments, the terms “lower side,” “lower portion,” “lower surface,” and the like, may be used to refer to directions facing downwardly with reference to a cross-section in the diagrams for ease of description, and the terms “upper side,” “upper portion,” “upper surfaces,” and the like, may be used to refer to directions opposing the above directions. The terms may be defined as above for ease of description, and the scope of right of the example embodiments is not particularly limited to the above terms.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, but may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

The terms used in the example embodiments are used to simply describe an example embodiment, and are not intended to limit the present disclosure. A singular term includes a plural form unless otherwise indicated.

While the example embodiments have been shown and described above, it will be apparent to those skilled in the art that modifications and variations could be made without departing from the scope of the present invention as defined by the appended claims.

What is claimed is:

1. An open pad structure, comprising:
an insulating layer;
a first pad disposed on the insulating layer;
a second pad disposed on the insulating layer and spaced apart from the first pad; and
a passivation layer disposed on the insulating layer, covering the first and second pads, and having an opening for opening at least a portion of each of the first and second pads, wherein the passivation layer covers the insulating layer between the first and second pads in the opening, and wherein t1 and t2 satisfy t1>t2, in which t1 is a thickness of a region of the passivation layer other than the opening, and t2 is a thickness of a region of the passivation layer between the first and second pads.

2. The open pad structure of claim 1, wherein t2, t3, and t4 satisfy t2≥t3 and t2≥t4, in which t3 is a thickness of the first pad and t4 is a thickness of the second pad.

3. The open pad structure of claim 2, wherein a, b, and c satisfy a≥c and b≥c, in which a is a depth of the opening to an exposed surface of the first pad, b is a depth of the opening to an exposed surface of the second pad, and c is a depth of the opening to an exposed surface of the passivation layer between the first and second pads.

4. The open pad structure of claim 1, wherein the passivation layer includes a thermosetting resin.

5. The open pad structure of claim 1, wherein the opening includes a first opening exposing at least a portion of a surface of the first pad, a second opening exposing at least a portion of a surface of the second pad, and a third opening penetrating a portion of the passivation layer between the first and second pads and exposing a surface of the passivation layer between the first and second pads.

6. The open pad structure of claim 1, further comprising:
an electronic component disposed on the passivation layer, and having first and second external electrodes connected to the first and second pads, respectively.

7. The open pad structure of claim 6, wherein the first and second pads and the first and second external electrodes are connected to each other by a solder.

8. The open pad structure of claim 1, wherein the passivation layer covers an edge of a surface of each of the first and second pads.

9. The open pad structure of claim 8, wherein regions of the passivation layer covering edges of surfaces of the first and second pads have a first region having a thickness substantially the same as a thickness of the region between the first and second pads, and a second region having a thickness greater than the thickness of the region between the first and second pads.

10. The open pad structure of claim 8, wherein regions of the passivation layer covering edges of surfaces of the first and second pads have thicknesses substantially the same as a thickness of the region between the first and second pads.

11. The open pad structure of claim 10, wherein the opening has a plurality of stepped portions disposed across exposed surfaces of the first and second pads, exposed surfaces of the passivation layer covering edges of surfaces of the first and second pads, and a surface of the passivation layer other than the opening.

12. The open pad structure of claim 1, wherein the region of the passivation layer having the thickness t1 is disposed directly on the insulating layer.

13. A semiconductor package, comprising:
a semiconductor chip having a connection pad;
an encapsulant covering at least a portion of the semiconductor chip;
an interconnect structure disposed on the semiconductor chip and the encapsulant and including a redistribution layer electrically connected to the connection pad; and
a passivation layer disposed on the interconnect structure and covering at least a portion of the redistribution layer,
wherein the redistribution layer includes first and second pads spaced apart from each other,
wherein the passivation layer has an opening exposing at least a portion of each of the first and second pads,
wherein the passivation layer covers the interconnect structure between the first and second pads in the opening, and
wherein t1 and t2 satisfy t1>t2, in which t1 is a thickness of a region of the passivation layer other than the opening, and t2 is a thickness of a region of the passivation layer between the first and second pads in the opening.

14. The semiconductor package of claim 13, further comprising:
an electronic component disposed on the passivation layer and having first and second external electrodes connected to the first and second pads, respectively.

15. The semiconductor package of claim 13, further comprising:
a frame having a through-hole,
wherein the semiconductor chip is disposed in the through-hole, and
wherein the encapsulant fills at least a portion of the through-hole.

16. The semiconductor package of claim 15,
wherein the frame includes a plurality of wiring layers, and
wherein the plurality of wiring layers are electrically connected to the connection pad through the redistribution layer.

17. The semiconductor package of claim 13, wherein the passivation layer includes a thermosetting resin.

18. The semiconductor package of claim 13, wherein the region of the passivation layer having the thickness t1 is disposed directly on an insulating layer of the interconnect structure.
